(19) United States
(12) Patent Application Publication
(10) Pub. No.: US 2022/0128660 A1
(43) Pub. Date: Apr. 28, 2022

(54) LIGHT RECEIVING DEVICE, HISTOGRAM GENERATION METHOD, AND DISTANCE MEASUREMENT SYSTEM

(71) Applicant: SONY SEMICONDUCTOR SOLUTIONS CORPORATION, KANAGAWA (JP)

(72) Inventor: NOBUHARU SUZUKI, KANAGAWA (JP)

(21) Appl. No.: 17/427,960

(22) PCT Filed: Jan. 30, 2020
(86) PCT No.: PCT/JP2020/003342

§ 371 Date: Aug. 3, 2021

(30) Foreign Application Priority Data
Feb. 13, 2019 (JP) 2019-023663

(51) Int. Cl. G01S 7/487; G01S 17/10; G01S 7/4865

(52) U.S. Cl. CPC G01S 7/487; G01S 7/4865; G01S 17/10

(57) ABSTRACT

The present technology relates to a light receiving device, a histogram generation method, and a distance measurement system that enable a histogram generation circuit to be realized in a small area and with low power consumption.

A light receiving device includes a measurement unit configured to measure time information from a light emission timing of a light source to a light receiving timing at which a light receiving element receives light, and a histogram generation circuit configured to generate a histogram that can accumulate N bits as frequency values on the basis of the time information. The histogram generation circuit includes a low-order bit generation unit configured to operate at a first speed, and generate a low-order bit of the N bits, and a high-order bit generation unit configured to operate at a second speed slower than the first speed, and generate a high-order bit of the N bits. The present technology can be applied to a distance measurement system or the like that detects a distance to a subject in a depth direction, for example, for example.

### TECHNICAL FIELD

The present technology relates to a light receiving device, a histogram generation method, and a distance measurement system, and relates particularly to a light receiving device, a histogram generation method, and a distance measurement system that enable a histogram generation circuit to be realized in a small area and with low power consumption.

### BACKGROUND ART

As one of distance measurement sensors for measuring a distance to a subject, there is a direct time of flight (ToF) sensor (for example, refer to Patent Document 1). The direct ToF sensor (hereinafter, will be simply referred to as a ToF sensor.) directly measures a distance on the basis of a time at which light is emitted toward a subject, and a time at which reflected light reflected from the subject is received.

In the ToF sensor, a time of flight of light from a time at which light is emitted, to a time at which reflected light is received is converted into distance data (hereinafter, will be referred to as ToF data.) by a time to digital converter (TDC). For removing the influence of ambient light or multipath, emission and reception of light are executed a plurality of times. Then, a histogram of ToF data corresponding to the plurality of times is generated, and ToF data with the largest frequency value is output as final ToF data.

In the ToF sensor, ToF data is output from the TDC at high rate due to the influence of ambient light, multipath light, or a pseudo light reception reaction caused by noise. For generating a histogram without missing data, it is necessary to operate a histogram generation circuit at the same high rate as an output rate from the TDC as well.

### CITATION LIST

### Patent Document

Patent Document 1: Japanese Patent Application Laid-Open No. 2010-91377

### SUMMARY OF THE INVENTION

### Problems to be Solved by the Invention

However, in a case where a histogram generation circuit is operated at a high rate corresponding to an output rate from a TDC, an area and operating power of the histogram generation circuit increase. This problem becomes more prominent if the resolution of a ToF sensor improves in the future.

The present technology has been devised in view of such a situation, and enables a histogram generation circuit to be realized in a small area and with low power consumption.

### Solutions to Problems

A light receiving device according the first aspect of the present technology includes a measurement unit configured to measure time information from a light emission timing of a light source to a light receiving timing at which a light receiving element receives light, and a histogram generation circuit configured to generate a histogram that can accumulate N bits as frequency values on the basis of the time information, in which the histogram generation circuit includes a low-order bit generation unit configured to operate at a first speed, and generate a low-order bit of the N bits, and a high-order bit generation unit configured to operate at a second speed slower than the first speed, and generate a high-order bit of the N bits.

A histogram generation method according the second aspect of the present technology is a histogram generation method of a light receiving device including a measurement unit configured to measure time information from a light emission timing of a light source to a light receiving timing at which a light receiving element receives light, and a histogram generation circuit configured to generate a histogram that can accumulate N bits as frequency values on the basis of the time information, including the measurement unit measuring the time information, and the histogram generation circuit operating at a first speed, and generating a low-order bit of the N bits in the histogram on the basis of the time information, and operating at a second speed slower than the first speed, and generating a high-order bit of the N bits in the histogram on the basis of the time information.

A distance measurement system according the third aspect of the present technology includes an illumination device configured to emit illumination light, and a light receiving device configured to receive reflected light of the illumination light, in which the light receiving device includes a measurement unit configured to measure time information from a light emission timing of a light source to a light receiving timing at which a light receiving element receives light, and a histogram generation circuit configured to generate a histogram that can accumulate N bits as frequency values on the basis of the time information, and the histogram generation circuit includes a low-order bit generation unit configured to operate at a first speed, and generate a low-order bit of the N bits, and a high-order bit generation unit configured to operate at a second speed slower than the first speed, and generate a high-order bit of the N bits.

In the first to third aspects of the present technology, time information from a light emission timing of a light source to a light receiving timing at which a light receiving element receives light is measured, and in the histogram generation circuit, a histogram that can accumulate N bits as frequency values is generated on the basis of the time information. The histogram generation circuit includes a low-order bit generation unit configured to operate at a first speed, and generate a low-order bit of the N bits, and a high-order bit generation unit configured to operate at a second speed slower than the first speed, and generate a high-order bit of the N bits.

The light receiving device and the distance measurement system may be independent devices, or may be modules incorporated in other devices.

### BRIEF DESCRIPTION OF DRAWINGS

FIG. 1 is a block diagram illustrating a configuration example of an embodiment of a distance measurement system to which the present technology is applied.

FIG. 2 is a block diagram illustrating a configuration example of a light receiving device in FIG. 1.

FIG. 3 is a diagram illustrating a circuit configuration example of a pixel.

FIG. 4 is a diagram describing an operation of the pixel in FIG. 3.

FIG. 5 is a diagram illustrating an example of a histogram to be generated by a signal processing unit.

FIG. 6 is a block diagram illustrating a configuration example of a signal processing unit according to a comparative example.

FIG. 7 is a block diagram illustrating a detailed configuration example of a signal processing unit in FIG. 2.

FIG. 8 is a diagram describing detection of a carry bit.

FIG. 9 is a flowchart describing distance measurement processing.

FIG. 10 is a plan view illustrating an arrangement example of components in a case where one chip having a stack structure of three substrates is included.

FIG. 11 is a diagram describing a usage example of a distance measurement system.

FIG. 12 is a block diagram illustrating an example of a schematic configuration of a vehicle control system.

FIG. 13 is an explanatory diagram illustrating an example of installation positions of a vehicle exterior information detection unit and an imaging unit.

### MODE FOR CARRYING OUT THE INVENTION

Hereinafter, a mode for carrying out the present technology (hereinafter, referred to as an embodiment) will be described. Note that the description will be given in the following order.

1. Configuration Example of Distance Measurement System

2. Configuration Example of Light Receiving Device

3. Configuration Example of Pixel Circuit

4. Configuration Example of Signal Processing Unit According to Comparative Example

5. Detailed Configuration Example of Signal Processing Unit of Present Technology

6. Distance Measurement Processing Performed by Distance Measurement System

7. Chip Configuration Example

8. Usage Example of Distance Measurement System

9. Application Example to Movable Body

### 1. Configuration Example of Distance Measurement System

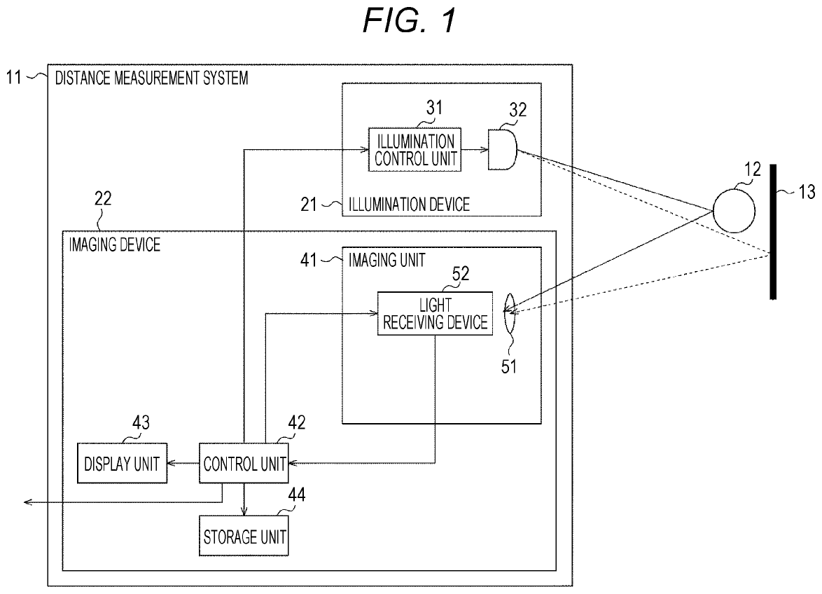

FIG. 1 is a block diagram illustrating a configuration example of an embodiment of a distance measurement system to which the present technology is applied.

A distance measurement system 11 is a system that captures a distance image using a ToF method, for example. Here, the distance image is an image obtained by detecting a distance in a depth direction from the distance measurement system 11 to a subject for each pixel. A signal of each pixel includes a distance pixel signal that is based on the detected distance.

The distance measurement system 11 includes an illumination device 21 and an imaging device 22.

The illumination device 21 includes an illumination control unit 31 and a light source 32.

Under the control of a control unit 42 of the imaging device 22, the illumination control unit 31 controls a pattern in which the light source 32 emits light. Specifically, in accordance with an emission code included in an emission signal supplied from the control unit 42, the illumination control unit 31 controls a pattern in which the light source 32 emits light. For example, the emission code includes two values corresponding to 1 (High) and 0 (Low). When the value of the emission code is 1, the illumination control unit 31 turns on the light source 32, and when the value of the emission code is 0, the illumination control unit 31 turns off the light source 32.

Under the control of the illumination control unit 31, the light source 32 emits light in a predetermined wavelength band. The light source 32 includes an infrared laser diode, for example. Note that the type of the light source 32 and the wavelength band of illumination light can be arbitrarily set in accordance with a use application or the like of the distance measurement system 11.

The imaging device 22 is a device that receives reflected light of light (illumination light) that has been emitted from the illumination device 21 and reflected by a subject 12, a subject 13, and the like. The imaging device 22 includes an imaging unit 41, the control unit 42, a display unit 43, and a storage unit 44.

The imaging unit 41 includes a lens 51 and a light receiving device 52.

The lens 51 forms an image of incident light on a light receiving surface of the light receiving device 52. Note that a configuration of the lens 51 is an arbitrary, and the lens 51 may include a plurality of lens units, for example.

The light receiving device 52 includes a sensor that uses a single photon avalanche diode (SPAD) as a light receiving element in each pixel, for example. Under the control of the control unit 42, the light receiving device 52 receives reflected light from the subject 12, the subject 13, and the like, converts a resultant pixel signal into distance information, and outputs the distance information to the control unit 42. The light receiving device 52 supplies, to the control unit 42 as a pixel value (distance pixel signal) of each pixel of a pixel array in which pixels are two-dimensionally arrayed in a matrix in a row direction and a column direction, a distance image storing a digital count value obtained by counting a time from when the illumination device 21 emits illumination light to when the light receiving device 52 receives the light. A light emission timing signal indicating a timing at which the light source 32 emits light is supplied also to the light receiving device 52 from the control unit 42.

Note that, by the distance measurement system 11 repeating light emission of the light source 32 and reception of the reflected light a plurality of times (for example, several thousands to several tens of thousands of times), the imaging unit 41 generates a distance image from which influence of ambient light, multipath, or the like has been removed, and supplies the distance image to the control unit 42.

The control unit 42 includes, for example, a control circuit or a processor such as a field programmable gate array (FPGA) or a digital signal processor (DSP), and the like. The control unit 42 performs control of the illumination control unit 31 and the light receiving device 52. Specifically, the control unit 42 supplies an emission signal to the illumination control unit 31, and supplies a light emission timing signal to the light receiving device 52. The light source 32 emits illumination light in accordance with the emission signal. The light emission timing signal may be an emission signal supplied to the illumination control unit 31. Furthermore, the control unit 42 supplies the distance image acquired from the imaging unit 41, to the display unit 43, and causes the display unit 43 to display the distance image. Moreover, the control unit 42 causes the storage unit 44 to store the distance image acquired from the imaging unit 41. Furthermore, the control unit 42 outputs the distance image acquired from the imaging unit 41, to the outside.

The display unit 43 includes a panel-shaped display device such as a liquid crystal display device or an organic Electro Luminescence (EL) display device, for example.

The storage unit 44 can include an arbitrary storage device or storage medium, or the like, and stores a distance image or the like.

### 2. Configuration Example of Light Receiving Device

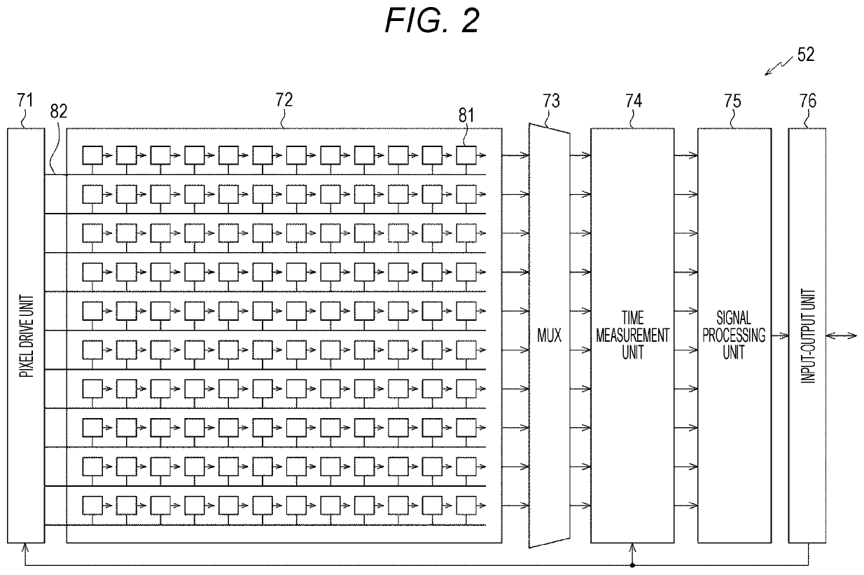

FIG. 2 is a block diagram illustrating a configuration example of the light receiving device 52.

The light receiving device 52 includes a pixel drive unit 71, a pixel array 72, a multiplexer (MUX) 73, a time measurement unit 74, a signal processing unit 75, and an input-output unit 76.

The pixel array 72 has a configuration in which pixels 81 are two-dimensionally arrayed in a matrix in the row direction and the column direction. Each of the pixels 81 detects the entry of a photon, and outputs a detection signal indicating a detection result, as a pixel signal. Here, the row direction refers to an array direction of the pixels 81 in a horizontal direction, and the column direction refers to an array direction of the pixels 81 in a vertical direction. Due to limitations of space, a pixel array configuration of the pixel array 72 that is illustrated in FIG. 2 includes ten rows and twelve columns, but the number of rows and the number of columns of the pixel array 72 are not limited to these, and can be arbitrary set.

For each pixel row, a pixel drive line 82 is wired in the horizontal direction to the matrix pixel array of the pixel array 72. The pixel drive line 82 transmits a drive signal for driving the pixels 81. The pixel drive unit 71 drives each of the pixels 81 by supplying a predetermined drive signal to each of the pixels 81 via the pixel drive lines 82. Specifically, the pixel drive unit 71 performs control in such a manner as to set at least a part of the plurality of pixels 81 two-dimensionally arrayed in a matrix, as active pixels, and set the remaining pixels 81 as inactive pixels, at a predetermined timing synchronized with a light emission timing signal supplied from the outside via the input-output unit 76. The active pixel is a pixel that detects the entry of a photon, and the inactive pixel is a pixel that does not detect the entry of a photon. As a matter of course, all of the pixels 81 of the pixel array 72 may be set as active pixels The detailed configuration of the pixels 81 will be described later.

Note that FIG. 2 illustrates the pixel drive line 82 as one wire, but the pixel drive line 82 may include a plurality of wires. One end of the pixel drive line 82 is connected to an output end of the pixel drive unit 71 that corresponds to each pixel row.

The MUX 73 selects an output from the active pixels in accordance with switching between active pixels and inactive pixels in the pixel array 72. Then, the MUX 73 outputs pixel signals input from the selected active pixels, to the time measurement unit 74.

On the basis of pixel signals of active pixels that are supplied from the MUX 73, and a light emission timing signal indicating a light emission timing of the light source 32, the time measurement unit 74 generates a count value corresponding to a time (time of flight of light) from when the light source 32 emits light to when active pixels receive the light. The light emission timing signal is supplied from the outside (the control unit 42 of the imaging device 22) via the input-output unit 76.

On the basis of the light emission of the light source 32 and the reception of the reflected light that are repeatedly executed a predetermined number of times (for example, several thousands to several tens of thousands of times), the signal processing unit 75 generates a histogram indicating a time (count value) until reception of reflected light, for each pixel. Then, by detecting a peak of the histogram, the signal processing unit 75 determines a time until light emitted from the light source 32 returns by being reflected by the subject 12 or the subject 13. The signal processing unit 75 generates a distance image storing a digital count value obtained by counting a time until the light receiving device 52 receives light, in each pixel, and supplies the distance image to the input-output unit 76. Alternatively, furthermore, the signal processing unit 75 may perform calculation for obtaining a distance to an object, on the basis of the determined time and a light speed, generate a distance image storing the calculation result in each pixel, and supply the distance image to the input-output unit 76.

The input-output unit 76 outputs a signal (distance image signal) of the distance image that is supplied from the signal processing unit 75, to the outside (the control unit 42). Furthermore, the input-output unit 76 acquires a light emission timing signal supplied from the control unit 42, and supplies the light emission timing to the pixel drive unit 71 and the time measurement unit 74.

### 3. Configuration Example of Pixel Circuit

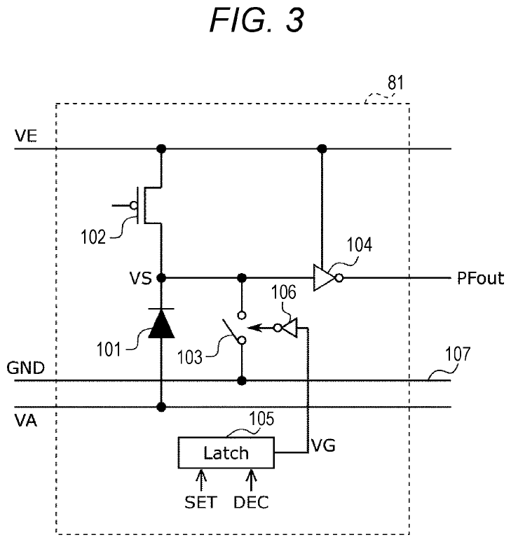

FIG. 3 illustrates a circuit configuration example of each of the plurality of pixels 81 arrayed in a matrix in the pixel array 72.

The pixel 81 in FIG. 3 includes an SPAD 101, a transistor 102, a switch 103, and an inverter 104. Furthermore, the pixel 81 also includes a latch circuit 105 and an inverter 106. The transistor 102 is formed by a P-type MOS transistor.

A cathode of the SPAD 101 is connected to a drain of the transistor 102, and also connected to an input terminal of the inverter 104 and one end of the switch 103. An anode of the SPAD 101 is connected to a source voltage VA (hereinafter, will also be referred to as an anode voltage VA).

The SPAD 101 is a photodiode (single photon avalanche photodiode) that causes avalanche amplification of generated electrons and outputs a signal of a cathode voltage VS, when incident light enters. The source voltage VA supplied to the anode of the SPAD 101 is set to a negative bias (negative potential) of about −20 V, for example.

The transistor 102 is a constant current source operating in a saturation region, and performs passive quench by functioning as a quenching resistor. A source of the transistor 102 is connected to a source voltage VE, and a drain is connected to the cathode of the SPAD 101, the input terminal of the inverter 104, and one end of the switch 103. Therefore, the source voltage VE is supplied also to the cathode of the SPAD 101. A pull-up resistor can also be used in place of the transistor 102 connected in series with the SPAD 101.

For detecting light (photon) with sufficient efficiency, a voltage (hereinafter, will be referred to as an excess bias.) larger than a breakdown voltage VBD of the SPAD 101 is applied to the SPAD 101. For example, if the breakdown voltage VBD of the SPAD 101 is set to 20 V, and a voltage larger than the breakdown voltage VBD by 3 V is applied, the source voltage VE to be supplied to the source of the transistor 102 is set to 3 V.

Note that the breakdown voltage VBD of the SPAD 101 drastically changes in accordance with a temperature or the like. Therefore, an applied voltage to be applied to the SPAD 101 is controlled (adjusted) in accordance with a change of the breakdown voltage VBD. For example, if the source voltage VE is set to a fixed voltage, the anode voltage VA is controlled (adjusted).

One end of both ends of the switch 103 is connected to the cathode of the SPAD 101, the input terminal of the inverter 104, and the drain of the transistor 102, and another end is connected to a ground connection line 107 connected to a ground (GND). The switch 103 can be formed by an N-type MOS transistor, for example, and turns on/off a gating control signal VG being an output of the latch circuit 105, in accordance with a gating inverted signal VG_I inverted by the inverter 106.

On the basis of a trigger signal SET and address data DEC that are supplied from the pixel drive unit 71, the latch circuit 105 supplies the gating control signal VG for controlling the pixel 81 to become an active pixel or an inactive pixel, to the inverter 106. The inverter 106 generates the gating inverted signal VG_I obtained by inverting the gating control signal VG, and supplies the gating inverted signal VG_I to the switch 103.

The trigger signal SET is a timing signal indicating a switching timing of the gating control signal VG, and the address data DEC is data indicating an address of a pixel to be set as an active pixel among the plurality of pixels 81 arrayed in the matrix in the pixel array 72. The trigger signal SET and the address data DEC are supplied from the pixel drive unit 71 via the pixel drive line 82.

The latch circuit 105 reads the address data DEC at a predetermined timing indicated by the trigger signal SET. Then, in a case where pixel addresses indicated by the address data DEC include a pixel address of itself (corresponding pixel 81), the latch circuit 105 outputs the gating control signal VG indicating Hi (1) for setting the corresponding pixel 81 as an active pixel. On the other hand, in a case where pixel addresses indicated by the address data DEC do not include a pixel address of itself (corresponding pixel 81), the latch circuit 105 outputs the gating control signal VG indicating Lo (0) for setting the corresponding pixel 81 as an inactive pixel.

Therefore, in a case where the pixel 81 is set as an active pixel, the gating inverted signal VG_I inverted by the inverter 106 and indicating Lo (0) is supplied to the switch 103. On the other hand, in a case where the pixel 81 is set as an inactive pixel, the gating inverted signal VG_I indicating Hi (1) is supplied to the switch 103. Accordingly, in a case where the pixel 81 is set as an active pixel, the switch 103 is turned off (unconnected), and in a case where the pixel 81 is set as an inactive pixel, the switch 103 is turned on (connected).

When the cathode voltage VS serving as an input signal indicates Lo, the inverter 104 outputs a detection signal PFout indicating Hi, and when the cathode voltage VS indicates Hi, the inverter 104 outputs the detection signal PFout indicating Lo. The inverter 104 is an output unit that outputs the entry of a photon to the SPAD 101, as the detection signal PFout.

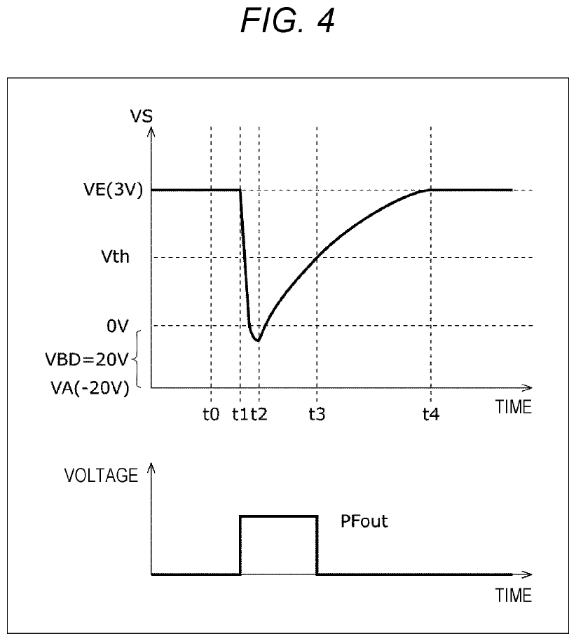

Next, an operation to be performed in a case where the pixel 81 is set as an active pixel will be described with reference to FIG. 4.

FIG. 4 is a graph indicating the cathode voltage VS of the SPAD 101 and the detection signal PFout that change in accordance with the entry of a photon.

First of all, in a case where the pixel 81 is set as an active pixel, the switch 103 is turned off as described above.

Because the source voltage VE (for example, 3 V) is supplied to the cathode of the SPAD 101, and the source voltage VA (for example, −20 V) is supplied to the anode, an inverse voltage larger than the breakdown voltage VBD (=20 V) is applied to the SPAD 101. The SPAD 101 is thereby set to a Geiger mode. In this state, the cathode voltage VS of the SPAD 101 is the same as the source voltage VE like the cathode voltage VS at a time t0 in FIG. 4, for example.

If a photon enters the SPAD 101 set to the Geiger mode, avalanche multiplication occurs, and current flows in the SPAD 101.

If avalanche multiplication occurs and current flows in the SPAD 101 at a time t1 in FIG. 4, after the time t1, by current flowing in the SPAD 101, current flows also in the transistor 102, and a voltage drop is caused by resistance components of the transistor 102.

If the cathode voltage VS of the SPAD 101 becomes lower than 0 V at a time t2, because an anode to cathode voltage of the SPAD 101 enters a state of being lower than the breakdown voltage VBD, avalanche amplification stops. Here, an operation of causing a voltage drop by flowing current generated by avalanche amplification, in the transistor 102, and stopping avalanche amplification by causing a state in which the cathode voltage VS is lower than the breakdown voltage VBD, in accordance with the caused voltage drop corresponds to a quench operation.

If avalanche amplification stops, current flowing in the resistor of the transistor 102 gradually decreases, and at a time t4, the cathode voltage VS returns to the original source voltage VE again, and a state in which a next new photon can be detected is caused (recharge operation).

The inverter 104 outputs the detection signal PFout indicating Lo, when the cathode voltage VS being an input voltage is equal to or larger than a predetermined threshold voltage Vth, and outputs the detection signal PFout indicating Hi, when the cathode voltage VS is smaller than the predetermined threshold voltage Vth. Accordingly, if a photon enters the SPAD 101, avalanche multiplication occurs, and the cathode voltage VS drops to fall below the threshold voltage Vth, the detection signal PFout is inverted from a low level to a high level. On the other hand, if avalanche multiplication of the SPAD 101 converges, and the cathode voltage VS rises to reach the threshold voltage Vth or more, the detection signal PFout is inverted from the high level to the low level.

Note that, in a case where the pixel 81 is set as an inactive pixel, the gating inverted signal VG_I indicating Hi (1) is supplied to the switch 103, and the switch 103 is turned on. If the switch 103 is turned on, the cathode voltage VS of the SPAD 101 is set to 0 V. Consequently, because the anode to cathode voltage of the SPAD 101 becomes equal to or smaller than the breakdown voltage VBD, a state in which the SPAD 101 does not react even if a photon enters the SPAD 101 is caused.

As described above, on the basis of the light emission of the light source 32 and the reception of the reflected light that are repeatedly executed a predetermined number of times, the signal processing unit 75 generates a histogram of a count value corresponding to a time until reception of reflected light, for each pixel. Note that, hereinafter, a count value corresponding to distance information to a subject will also be referred to as ToF data.

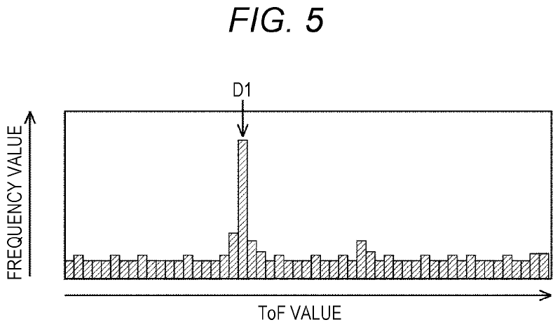

FIG. 5 illustrates an example of a histogram of a predetermined pixel 81 that has been generated by the signal processing unit 75.

A horizontal axis of the histogram illustrated in FIG. 5 indicates a value of ToF data (ToF value), and a vertical axis indicates the number of times (frequency value) each ToF value is detected. In this example, a peak of the histogram is a ToF value indicated by D1, and this ToF value is output as ToF data of the pixel 81.

In the signal processing unit 75, a histogram as illustrated in FIG. 5 is calculated for each pixel of the pixel array 72, and a distance image in which ToF data of a peak of the histogram is stored in each pixel is output to the control unit 42 (FIG. 1).

A circuit area of a histogram generation circuit that generates a histogram as illustrated in FIG. 5 increases if the resolution (spacial solution or temporal resolution) of a distance measurement system is improved.

In view of the foregoing, hereinafter, a configuration of a signal processing unit that that can suppress a circuit area of a histogram generation circuit, which is applied to the signal processing unit 75 of the light receiving device 52, will be described. Nevertheless, hereinafter, a configuration example of a signal processing unit 301 being a comparative example to be compared with the signal processing unit 75 to which the present technology is applied will be described first, and then, a configuration of the signal processing unit 75 of the light receiving device 52 will be described.

### 4. Configuration Example of Signal Processing Unit According to Comparative Example

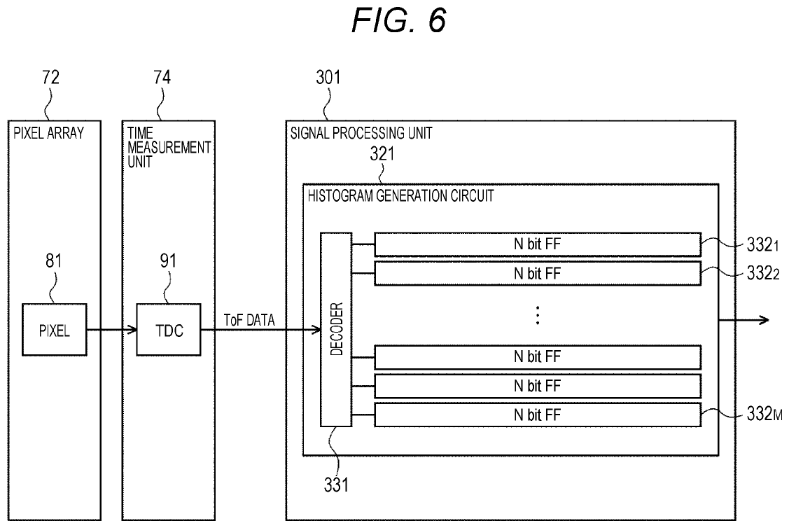

FIG. 6 is a block diagram illustrating a configuration example of the signal processing unit 301 according to a comparative example.

The signal processing unit 301 in FIG. 6 includes one histogram generation circuit 321 for one time to digital converter (TDC) 91 provided in a time measurement unit 74. The histogram generation circuit 321 is a circuit that generates one histogram that can accumulate N bits as frequency values. The histogram generation circuit 321 includes a decoder 331 and M flip-flop circuits (hereinafter, will be referred to as FF circuits.) 332₁ to 332_{M}.

Hereinafter, the M FF circuits 332₁ to 332_{M} will be simply referred to as the FF circuits 332 in a case where specific discrimination is not required. The FF circuit 332 is an N bit memory that stores a frequency value of a predetermined ToF value. One FF circuit 332 corresponds to one bin of the histogram in FIG. 5, and M is a sufficient value (number of bins) for a distance that can be measured by a ToF sensor. A bit depth N of the FF circuit 332 is a sufficient value for a frequency value that can be taken by each bin.

The TDC 91 of the time measurement unit 74 is provided to correspond to one or more pixels 81 of the pixel array 72. In FIG. 6, the pixel array 72 and the time measurement unit 74 are illustrated for clarifying a correspondence relationship with the histogram generation circuit 321.

In other words, the TDC 91 of the time measurement unit 74 is provided for one or more pixels 81 of the pixel array 72. For example, in a case where all pixels 81 two-dimensionally arrayed in a matrix are simultaneously operated as active pixels, the pixel 81 and the TDC 91 are provided on a one-to-one basis, and the time measurement unit 74 includes the same number of TDCs 91 as the number of pixels of the pixel array 72. Furthermore, for example, in a case where one TDC 91 is provided for a plurality of pixels 81 constituting one row of the pixel array 72, the time measurement unit 74 includes the same number of TDCs 91 as the number of pixel rows of the pixel array 72. Accordingly, the number of TDCs 91 included in the time measurement unit 74 is determined in accordance with the number of pixels required to be simultaneously set as active pixels in one light reception, or the like.

If an output of the pixels 81 set as active pixels is appropriately selected in the MUX 73, pixel signals of the pixels 81 set as active pixels, that is to say, the above-described detection signals PFout are input to the TDC 91. The TDC 91 counts a time (period) for which the detection signal PFout indicating Hi is input, and outputs a count value (ToF value) indicating a count result, to the histogram generation circuit 321 as ToF data. The TDC 91 corresponds to a measurement unit that measures time information from a light emission timing of the light source 32 to a light receiving timing at which the pixel 81 receives light.

The ToF data from the TDC 91 is decoded by the decoder 331 and is stored into any of the FF circuits 332₁ to 332_{M} corresponding to a ToF value. In other words, the decoder 331 selects any of the FF circuits 332₁ to 332_{M} in accordance with input ToF data, and counts up a frequency value of the selected FF circuit 332.

### 5. Detailed Configuration Example of Signal Processing Unit of Present Technology

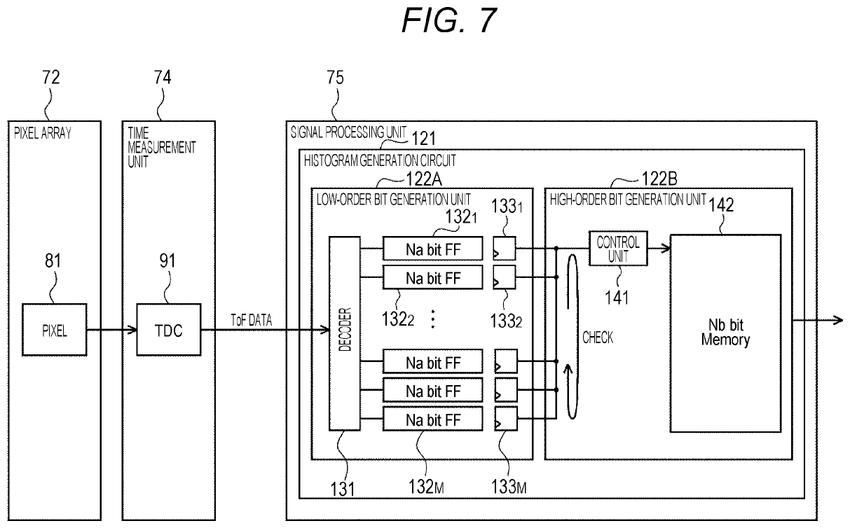

FIG. 7 is a block diagram illustrating a detailed configuration example of a signal processing unit to which the present technology is applied, and illustrating a detailed configuration example of the signal processing unit 75 in FIG. 2.

Note that, also in FIG. 7, similarly to FIG. 6, corresponding configurations of the pixel array 72 and the time measurement unit 74 are also illustrated.

The signal processing unit 75 in FIG. 7 includes one histogram generation circuit 121 for one TDC 91 provided in a time measurement unit 74. The histogram generation circuit 121 is a circuit that generates one histogram that can accumulate N bits as frequency values. A relationship between the pixel 81 of the pixel array 72 and the TDC 91 of the time measurement unit 74 is similar to that in the case illustrated in FIG. 5.

The histogram generation circuit 121 divides frequency values of N bits into a low-order Na bit and a high-order Nb bit (N=Na+Nb), and includes a low-order bit generation unit 122A that generates and stores a low-order Na bit, and a high-order bit generation unit 122B that generates and stores a high-order Nb bit. For example, in a case where a bit depth N of the total frequency values is set to 24 bits, a bit depth Na of a low-order bit is 8 (Na=8), and a bit depth Nb of a high-order bit is 16 (Nb=16), or the like.

The low-order bit generation unit 122A includes a decoder 131, M flip-flop circuits (hereinafter, described as FF circuits.) 132₁ to 132_{M}, and M carry bits 133₁ to 133_{M}. The M FF circuits 132₁ to 132_{M} and the M carry bits 133₁ to 133_{M} correspond to each other on a one-to-one basis.

Hereinafter, the M FF circuits 132₁ to 132_{M} will be simply referred to as the FF circuits 132 in a case where specific discrimination is not required, and the M carry bits 133₁ to 133_{M} will be simply referred to as the carry bits 133 in a case where specific discrimination is not required.

The high-order bit generation unit 122B includes a control unit 141 and an Nb bit memory unit 142.

The decoder 131 performs an operation similar to the decoder 331 in FIG. 6. More specifically, the decoder 131 selects any of the FF circuits 132₁ to 132_{M} corresponding to a ToF value of input ToF data, and counts up a low-order Na bit of a frequency value of the selected FF circuit 332.

The M FF circuits 132 stores a low-order Na bit of a frequency value of each ToF value.

The carry bit 133 detects carry of an Na bit of the corresponding FF circuit 132, and in a case where carry occurs, turns on (“1”) a bit (hereinafter, will be referred to as a carry bit). The on-state (“1”) of the carry bit is thereafter detected by the control unit 141 of the high-order bit generation unit 122B, and then is reset to an off-state (“0”)

The control unit 141 of the high-order bit generation unit 122B controls the memory unit 142 on the basis of the M carry bits 133₁ to 133_{M} of the low-order bit generation unit 122A. For example, the control unit 141 periodically checks bit states of the M carry bits 133₁ to 133_{M}, that is to say, the on-state (“1”) or the off-state (“0”), and counts up a frequency value of a high-order Nb bit of a bin of the memory unit 142 corresponding to the carry bit 133 of which the on-state is detected.

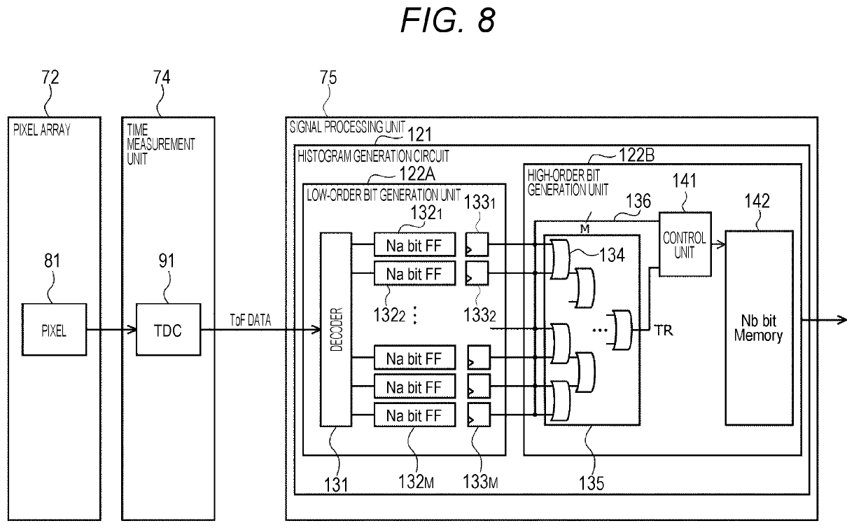

Alternatively, furthermore, in a case where any of the M carry bits 133 is turned on, a trigger signal TR indicating the on-state may be supplied to the control unit 141. In a case where the control unit 141 acquires the trigger signal TR, the control unit 141 checks bit states of the M carry bits 133₁ to 133_{M}, and counts up a frequency value of a high-order Nb bit of a bin of the memory unit 142 corresponding to the carry bit 133 of which the on-state is detected. For example, a configuration as illustrated in FIG. 8 can be employed. More specifically, a trigger signal generation unit 135 including OR circuits 134 on a plurality of columns is provided, and the trigger signal generation unit 135 generates the trigger signal TR on the basis of a logical sum of detection signals indicating the on-state of the M carry bits 133, and supplies the trigger signal TR to the control unit 141, and the control unit 141 checks bit states of the carry bits 133 via M signal lines 136.

The control unit 141 resets a bit state of a carry bit 133 that has updated a frequency value of a predetermined bin in the memory unit 142, from the on-state to the off-state.

The memory unit 142 includes a static random access memory (SRAM), a dynamic random access (DRAM), or the like, for example, and stores a high-order Nb bit of a frequency value of each of M ToF values.

The low-order bit generation unit 122A is required to be able to process a count operation of a frequency value at a timing of ToF data supplied from the TDC 91, that is to say, at an output rate of ToF data. Therefore, the low-order bit generation unit 122A counts and stores a frequency value of a low-order Na bit using the FF circuit 132 that can perform a high-speed operation.

On the other hand, because a toggle rate becomes ½ as a bit becomes a higher-order bit, the memory unit 142 on the high-order bit side needs not operate at as high speed as an output rate of ToF data. For example, if a bit depth Na of a low-order bit that performs a high-speed operation is set to 8 bits (Na=8), and an output rate of ToF data is set to 256 MHz (3.9 nsec interval), the high-order bit side is only required to operate at a throughput of 1 MHz. Therefore, the high-order bit generation unit 122B that stores a high-order Nb bit can include an SRAM or a DRAM.

Generally, an FF circuit can perform a high-speed operation, but wiring density becomes low density. On the other hand, an SRAM and a DRAM cannot operate at as high speed as an FF circuit, but have high wiring density. Accordingly, as compared with a case where all memories for storing frequency values of N bits are formed by FF circuits as in the histogram generation circuit 321 in FIG. 6, the signal processing unit 75 can be realized in a smaller area. Furthermore, because the high-order bit generation unit 122B can perform a low-speed operation, power consumption can also be suppressed.

As described above, the histogram generation circuit 121 of the signal processing unit 75 in FIG. 7 can be realized in a smaller area and with lower power consumption as compared with the histogram generation circuit 321 of the signal processing unit 301 in FIG. 6.

### 6. Distance Measurement Processing Performed by Distance Measurement System

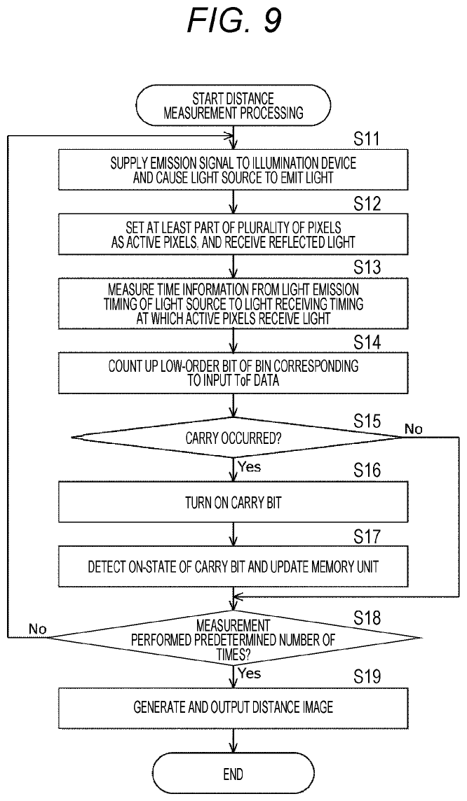

Distance measurement processing to be performed by the distance measurement system 11 will be described with reference to the flowchart in FIG. 9. The processing is started when a start instruction of distance measurement processing is issued to the imaging device 22 of the distance measurement system 11, for example.

First of all, in Step S11, the control unit 42 of the imaging device 22 supplies an emission signal to the illumination control unit 31 of the illumination device 21, and causes the light source 32 to emit light. The light source 32 emits light in a predetermined wavelength band in accordance with an emission code included in the emission signal. A light emission timing signal indicating a timing at which the light source 32 emits light is supplied also to the light receiving device 52 from the control unit 42.

In Step S12, the light receiving device 52 sets at least part of the plurality of pixels 81 of the pixel array 72 active pixels, and receives reflected light of light that has been emitted by the light source 32 and reflected by a subject. The pixels 81 set as active pixels detect entry of photons to the SPAD 101, and output the detection signals PFout indicating Hi, to the TDC 91.

In Step S13, the TDC 91 measures time information from a light emission timing of the light source 32 to a light receiving timing at which the active pixels receive light. Specifically, the TDC 91 counts a time (period) for which the detection signal PFout indicating Hi is input, and outputs a count value indicating a count result, to the histogram generation circuit 121 as ToF data.

In Step S14, the decoder 131 counts up a low-order bit Na of a bin corresponding to ToF data (ToF value) input from the TDC 91. More specifically, the decoder 131 selects any of the FF circuits 132₁ to 132_{M} corresponding to a ToF value of input ToF data, and counts up a frequency value of the selected FF circuit 332.

In Step S15, the M carry bits 133 detect carry of low-order bits Na of the corresponding FF circuits 132. In other words, the carry bit 133 determines whether or not carry of a low-order bit Na of the corresponding FF circuit 132 has occurred.

In a case where it is determined in Step S15 that carry has occurred, the processing proceeds to Step S16, and the carry bit 133 that has detected carry turns on a bit (carry bit) of itself.

Then, in Step S17, the control unit 141 detects the on-state of a predetermined carry bit of the M carry bits 133₁ to 133_{M}, and updates the memory unit 142. In other words, the control unit 141 counts up a frequency value of a high-order Nb bit of a bin of the memory unit 142 corresponding to the carry bit 133 of which the on-state is detected.

On the other hand, in a case where it is determined in Step S15 that carry has not occurred, the processing in Steps S16 and S17 is skipped, and the processing proceeds to Step S18.

In Step S18, the histogram generation circuit 121 determines whether or not measurement has performed a preliminarily determined predetermined number of times (for example, several thousands to several tens of thousands of times).

In a case where it is determined in Step S18 that measurement has not performed a predetermined number of times yet, the processing returns to Step S11, and the above-described processing in Steps S11 to S18 is repeated. In other words, the generation (update) of a histogram that is based on input ToF data is continued.

On the other hand, in a case where it is determined in Step S18 that measurement has performed a predetermined number of times, the processing proceeds to Step S19, and the signal processing unit 75 generates a distance image storing a ToF value of a peak as a pixel value, for each of the pixels 81 set as active pixels, referring to a frequency value of a histogram of a histogram hold circuit 151, and outputs the distance image to the control unit 42 via the input-output unit 76. The control unit 42 outputs the distance image acquired from the imaging unit 41, to the outside, and ends the distance measurement processing.

In the above-described processing in Step S18, the signal processing unit 75 generates a histogram of ToF values for each pixel, and outputs a distance image storing a ToF value of a peak in each pixel, to the control unit 42. However, the signal processing unit 75 may generate a distance image storing a distance to an object that has been calculated on the basis of a time (ToF value) and a light speed, in each pixel as a pixel value, and output the distance image to the control unit 42.

Alternatively, furthermore, the signal processing unit 75 may output a histogram generated by the histogram generation circuit 121 for each pixel, to the control unit 42 as-is. In this case, the signal processing unit 75 may output N bit data including a high-order Nb bit and a low-order Na bit, or may output only a high-order Nb bit because a low-order Na bit is assumed to a noise component.

### 7. Chip Configuration Example

The light receiving device 52 can have a configuration of one chip (semiconductor chip) having a stack structure in which three substrates (dice) are stacked, for example.

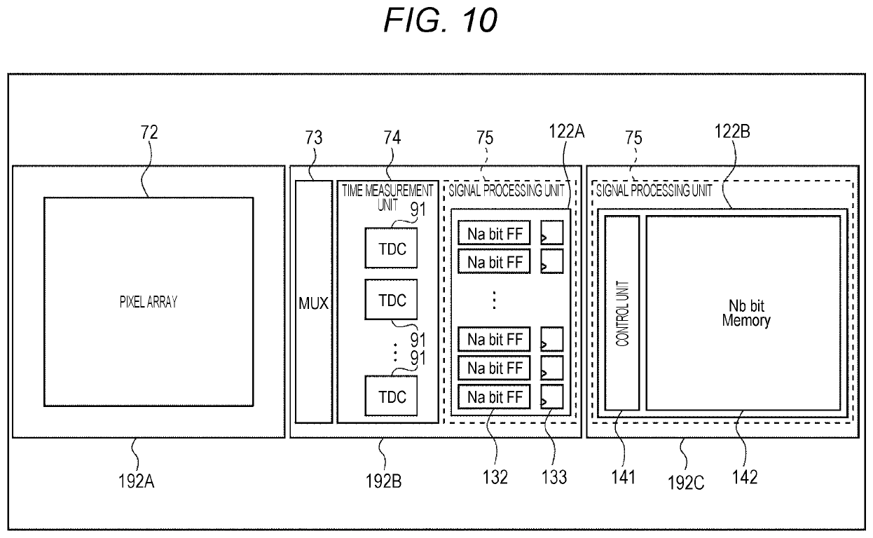

FIG. 10 illustrates an arrangement example of components in a case where the light receiving device 52 includes one chip having a stack structure of three substrates.

The light receiving device 52 has a configuration in which a first substrate 192A, a second substrate 192B, and a third substrate 192C are stacked. The first substrate 192A and the second substrate 192B are electrically connected via a penetration via or by metal bonding of Cu—Cu, and the second substrate 192B and the third substrate 192C are electrically connected via a penetration via or by metal bonding of Cu—Cu.

The pixel array 72 is formed on the first substrate 192A. The MUX 73, the time measurement unit 74, and a part of the signal processing unit 75 are arranged on the second substrate 192B. For example, the decoder 131, the M FF circuits 132₁ to 132_{M}, the M carry bits 133₁ to 133_{M}, and the like of the signal processing unit 75 are arranged on the second substrate 192B. In FIG. 10, the illustration of the decoder 131 is omitted.

A remaining part of the signal processing unit 75 that is not arranged on the second substrate 192B, such as the control unit 141 and the Nb bit memory unit 142, for example, is arranged on the third substrate 192C. For example, output terminals of the M carry bits 133₁ to 133_{M} on the second substrate 192B and the control unit 141 on the third substrate 192C are connected by a Through Silicon Via (TSV) or the like.

In the above-described example, the description has been given of an example in which frequency values of N bits are divided into two types of bits corresponding to a low-order Na bit and a high-order Nb bit, but the number of types of bits is not limited to two, and frequency values of N bits may be divided into three types of bits corresponding to a low-order Na bit, a middle-order Nb bit, and a high-order Nc bit (N=Na+Nb+Nc), for example. In this case, for example, memory units for storing the respective types of bits can be formed by different memory circuits in such a manner that a memory unit for storing a low-order Na bit is formed by an FF circuit, a memory unit for storing a middle-order Nb bit is formed by an SRAM, and a memory unit for storing a high-order Nc bit is formed by a DRAM.

### 8. Usage Example of Distance Measurement System

The application of the present technology is not limited to application to a distance measurement system. More specifically, the present technology can be applied to general electronic devices such as a smartphone, a tablet terminal, a mobile phone, a personal computer, a game machine, a television receiver, a wearable terminal, a digital still camera, or a digital video camera, for example. The above-described imaging unit 41 may have a module configuration in which the lens 51 and the light receiving device 52 are collectively packaged, or may have a configuration in which the lens 51 and the light receiving device 52 are separately formed, and only the light receiving device 52 is formed as one chip.

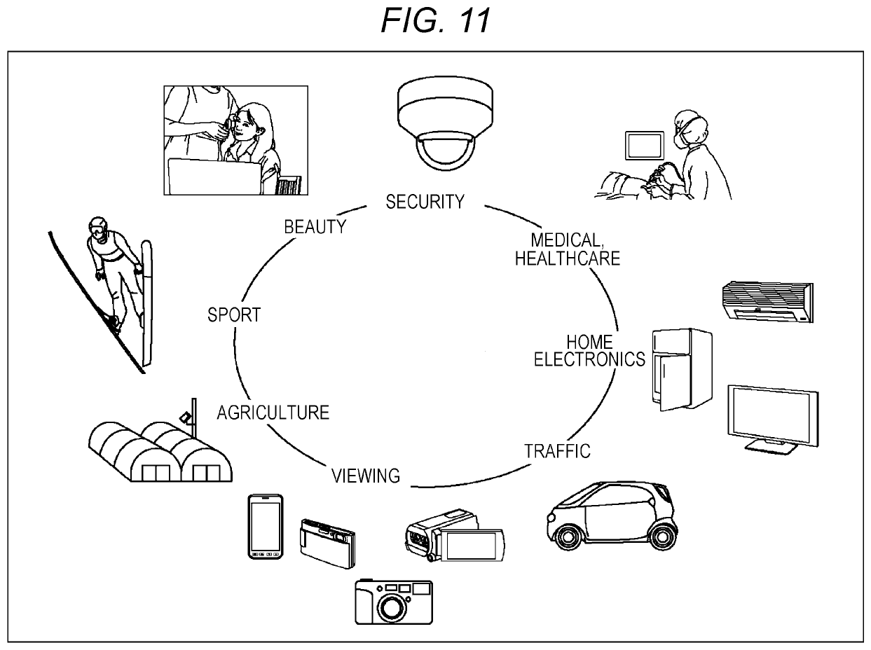

FIG. 11 is a diagram illustrating a usage example of the above-described distance measurement system 11 or the light receiving device 52.

The above-described distance measurement system 11 can be used in various cases of sensing light such as visible light, infrared light, ultraviolet, or an X-ray, for example, as described below.

A device that captures an image to be used for viewing, such as a digital camera or a portable device equipped with a camera function
A device to be used for traffic, such as an in-vehicle sensor that captures images of a front side, a rear side, and a periphery of an automobile, the inside of the vehicle, and the like for safe driving such as an automatic stop, recognition of a state of a driver, and the like, a monitoring camera that monitors a running vehicle and a road, or a distance measurement sensor that measures a distance such as an inter-vehicular distance
A device used in home electronics such as a TV, a refrigerator, or an air conditioner, for capturing an image of a gesture of a user, and performing a device operation suitable for the gesture
A device used for medical and healthcare, such as an endoscope or a device that captures an image of blood vessels by receiving infrared light
A device used for security, such as a monitoring camera intended for crime prevention, or a camera intended for human authentication
A device used for beauty, such as a skin measuring device that captures an image of a skin, or a microscope that captures an image of a skin of scalp
A device used for sport, such as an action camera or a wearable camera intended for sport or the like
A device used for agriculture, such as a camera for monitoring a state of a field or a crop

### 9. Application Example to Movable Body

The technology according to the present disclosure (present technology) can be applied to various products. For example, the technology according to the present disclosure can be implemented as a device mounted on a movable body of any type of an automobile, an electric car, a hybrid electric car, a motorbike, a bicycle, a personal mobility, a plane, a drone, a ship, a robot, and the like.

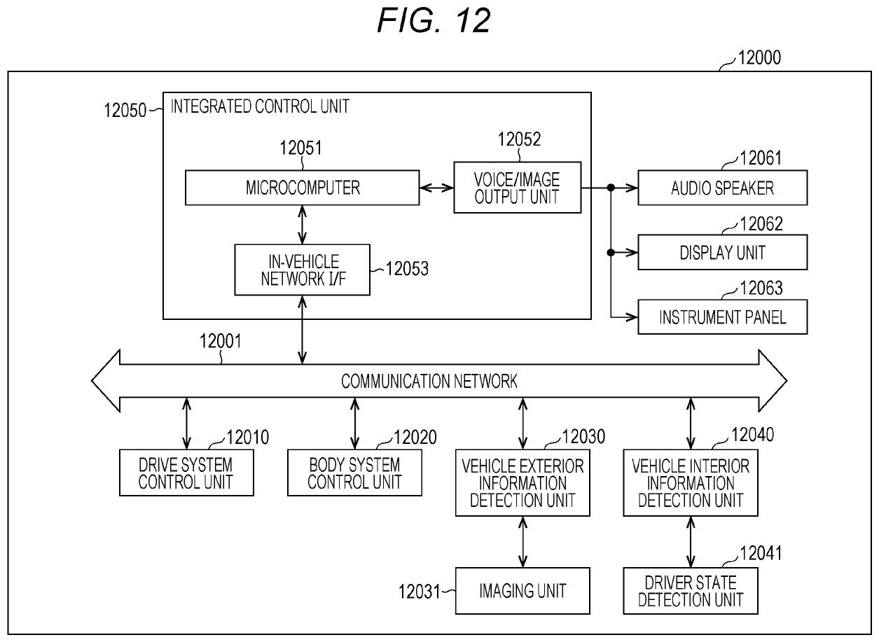

FIG. 12 is a block diagram illustrating a schematic configuration example of a vehicle control system being an example of a movable body control system to which the technology according to the present disclosure can be applied.

A vehicle control system 12000 includes a plurality of electronic control units connected via a communication network 12001. In the example illustrated in FIG. 12, the vehicle control system 12000 includes a drive system control unit 12010, a body system control unit 12020, a vehicle exterior information detection unit 12030, a vehicle interior information detection unit 12040, and an integrated control unit 12050. Furthermore, as functional configurations of the integrated control unit 12050, a microcomputer 12051, a voice/image output unit 12052, and an in-vehicle network interface (I/F) 12053 are illustrated.

The drive system control unit 12010 controls operations of a device related to a drive system of a vehicle in accordance with various programs. For example, the drive system control unit 12010 functions as a control device of a drive force generation device for generating drive force of a vehicle, such as an internal-combustion engine or a driving motor, a drive force transmission mechanism for transmitting drive force to wheels, a steering mechanism for adjusting a steering angle of the vehicle, a braking device for generating braking force of the vehicle, and the like.

The body system control unit 12020 controls operations of various devices provided in a vehicle body, in accordance with various programs. For example, the body system control unit 12020 functions as a control device of a keyless entry system, a smart key system, a powered window device, or various lamps such as a headlamp, a back lamp, a brake lamp, a blinker, or a fog lamp. In this case, radio waves transmitted from a mobile device substituting for a key, or signals of various switches can be input to the body system control unit 12020. The body system control unit 12020 receives input of these radio waves or signals, and controls a door lock device of the vehicle, the powered window device, lamps, and the like.

The vehicle exterior information detection unit 12030 detects information regarding the outside of the vehicle on which the vehicle control system 12000 is mounted. For example, an imaging unit 12031 is connected to the vehicle exterior information detection unit 12030. The vehicle exterior information detection unit 12030 causes the imaging unit 12031 to capture an image of the outside of the vehicle, and receives the captured image. On the basis of the received image, the vehicle exterior information detection unit 12030 may perform object detection processing or distance detection processing of a human, a car, an obstacle, a road sign, characters on a road, and the like.

The imaging unit 12031 is an optical sensor that receives light and outputs an electrical signal corresponding to a light reception amount of the light. The imaging unit 12031 can output an electrical signal as an image, and output an electrical signal as information regarding distance measurement. Furthermore, light to be received by the imaging unit 12031 may be visible light, or may be invisible light such as infrared light.

The vehicle interior information detection unit 12040 detects information regarding the vehicle interior. For example, a driver state detection unit 12041 that detects a state of a driver is connected to the vehicle interior information detection unit 12040. The driver state detection unit 12041 includes a camera for capturing an image of a driver, for example. On the basis of detection information input from the driver state detection unit 12041, the vehicle interior information detection unit 12040 may calculate a fatigue degree or a concentration degree of the driver, or may determine whether or not the driver dozes off.

On the basis of information regarding the vehicle interior or vehicle exterior that is acquired by the vehicle exterior information detection unit 12030 or the vehicle interior information detection unit 12040, the microcomputer 12051 can calculate control target values of the drive force generation device, the steering mechanism, or the braking device, and output a control command to the drive system control unit 12010. For example, the microcomputer 12051 can perform cooperative control intended to implement functions of an advanced driver assistance system (ADAS) including collision avoidance or shock mitigation of the vehicle, follow-up driving that is based on an inter-vehicular distance, maintained vehicle speed driving, collision warning of the vehicle, lane deviation warning of the vehicle, or the like.

Furthermore, the microcomputer 12051 can perform cooperative control intended for automated driving of autonomously driving without depending on the operation of a driver, or the like, by controlling the drive force generation device, the steering mechanism, the braking device, or the like on the basis of information regarding the periphery of the vehicle that is acquired by the vehicle exterior information detection unit 12030 or the vehicle interior information detection unit 12040.

Furthermore, the microcomputer 12051 can output a control command to the body system control unit 12020 on the basis of information regarding the vehicle exterior that is acquired by the vehicle exterior information detection unit 12030. For example, the microcomputer 12051 can perform cooperative control intended to achieve antidazzle by controlling a headlamp in accordance with a position of a leading vehicle or an oncoming vehicle that has been detected by the vehicle exterior information detection unit 12030, and switching high beam to low beam, or the like.

The voice/image output unit 12052 transmits an output signal of at least one of voice or an image to an output device that can visually or aurally notify an occupant of the vehicle or the vehicle exterior of information. In the example in FIG. 12, an audio speaker 12061, a display unit 12062, and an instrument panel 12063 are exemplified as output devices. The display unit 12062 may include at least one of an onboard display or a headup display, for example.

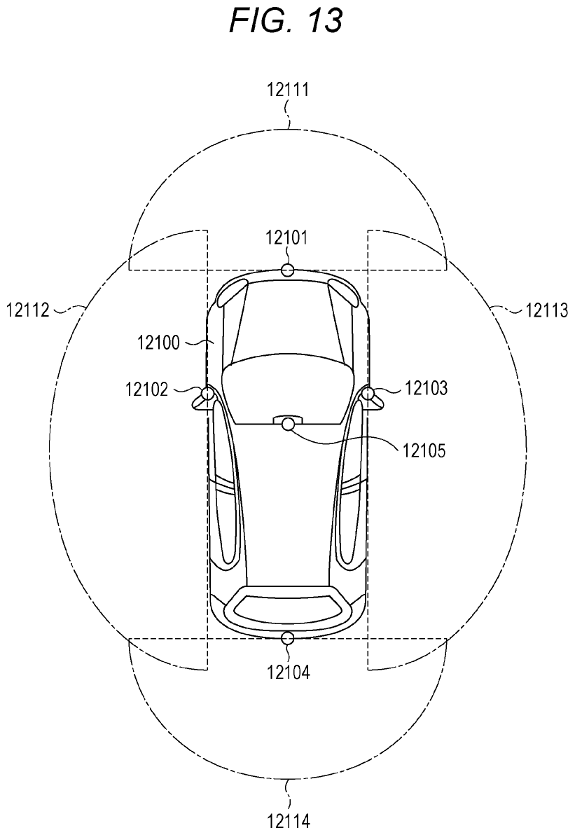

FIG. 13 is a diagram illustrating an example of an installation position of the imaging unit 12031.

In FIG. 13, a vehicle 12100 includes imaging units 12101, 12102, 12103, 12104, and 12105 as the imaging unit 12031.

The imaging units 12101, 12102, 12103, 12104, and 12105 are provided at positions such as a front nose of the vehicle 12100, side mirrors, a rear bumper, a backdoor, and an upper part of a front window inside a vehicle room, for example. The imaging unit 12101 provided at the front nose and the imaging unit 12105 provided at the upper part of the front window inside the vehicle room mainly acquire images of a front side of the vehicle 12100. The imaging units 12102 and 12103 provided at the side mirrors mainly acquire images of the sides of the vehicle 12100. The imaging unit 12104 provided at the rear bumper or the backdoor mainly acquires images of the back side of the vehicle 12100. The images of the front side that are acquired by the imaging units and 12101 and 12105 are mainly used for the detection of a leading vehicle, a pedestrian, an obstacle, a traffic light, a traffic sign, a traffic lane, or the like.

Note that FIG. 13 illustrates an example of image capturing ranges of the imaging units 12101 to 12104. An image capturing range 12111 indicates an image capturing range of the imaging unit 12101 provided at the front nose, image capturing ranges 12112 and 12113 respectively indicate image capturing ranges of the imaging units 12102 and 12103 provided at the side mirrors, and an image capturing range 12114 indicates an image capturing range of the imaging unit 12104 provided at the rear bumper or the backdoor. For example, a birds-eye image of the vehicle 12100 viewed from above is obtained by overlapping image data captured by the imaging units 12101 to 12104.

At least one of the imaging units 12101 to 12104 may have a function of acquiring distance information. For example, at least one of the imaging units 12101 to 12104 may be a stereo camera including a plurality of image sensors, or may be an image sensor including pixels for phase difference detection.

For example, by obtaining a distance to each three-dimensional object in the image capturing ranges 12111 to 12114, and a temporal variation (relative speed with respect to the vehicle 12100) of the distance, on the basis of distance information acquired from the imaging units 12101 to 12104, the microcomputer 12051 can especially extract, as a leading vehicle, a three-dimensional object that is the closest three-dimensional object existing on a travelling path of the vehicle 12100, and is running at a predetermined speed (for example, equal to or larger than 0 km/h) in substantially the same direction as the vehicle 12100. Moreover, the microcomputer 12051 can preliminarily set an inter-vehicular distance to be ensured in front of a leading vehicle, and perform automatic brake control (including follow-up stop control), automatic acceleration control (including follow-up departure control), and the like. In this manner, cooperative control intended for automated driving of autonomously driving without depending on the operation of a driver, or the like can be performed.

For example, on the basis of distance information acquired from the imaging units 12101 to 12104, the microcomputer 12051 can extract three-dimensional object data regarding a three-dimensional object, while classifying three-dimensional objects into other three-dimensional objects such as a two-wheeled vehicle, a standard-sized vehicle, a large-sized vehicle, a pedestrian, and a telephone pole, and use the extracted three-dimensional object data for automatic avoidance of an obstacle. For example, the microcomputer 12051 identifies obstacles near the vehicle 12100, as an obstacle visible by a driver of the vehicle 12100, and an obstacle less-visible by the driver. Then, the microcomputer 12051 determines collision risk indicating a degree of risk of collision with each obstacle, and when the collision risk is equal to or larger than a setting value and there is a possibility of collision, the microcomputer 12051 can perform drive assist for collision avoidance by outputting a warning to the driver via the audio speaker 12061 or the display unit 12062, and performing forced deceleration or avoidance steering via the drive system control unit 12010.

At least one of the imaging units 12101 to 12104 may be an infrared camera that detects infrared light. For example, the microcomputer 12051 can recognize a pedestrian by determining whether or not a pedestrian exists in captured images of the imaging units 12101 to 12104. The recognition of a pedestrian is performed by a procedure of extracting feature points in captured images of the imaging units 12101 to 12104 serving as infrared cameras, and a procedure of determining whether or not a detected object is a pedestrian, by performing pattern matching processing on a series of feature points indicating an outline of the object, for example. If the microcomputer 12051 determines that a pedestrian exists in captured images of the imaging units 12101 to 12104, and recognizes the pedestrian, the voice/image output unit 12052 controls the display unit 12062 to display a rectangular profile line for enhancement, with being superimposed on the recognized pedestrian. Furthermore, the voice/image output unit 12052 may control the display unit 12062 to display an icon indicating the pedestrian, or the like at a desired position.

Heretofore, an example of the vehicle control system to which the technology according to the present disclosure can be applied has been described. The technology according to the present disclosure can be applied to the imaging unit 12031 or the like among the configurations described above. Specifically, for example, the distance measurement system 11 in FIG. 1 can be applied to the imaging unit 12031. The imaging unit 12031 is a LIDAR, for example, and is used for detecting an object near the vehicle 12100 and a distance to the object. By applying the technology according to the present disclosure to the imaging unit 12031, detection accuracy of an object near the vehicle 12100 and a distance to the object improves. Consequently, for example, it becomes possible to perform collision warning of a vehicle at an appropriate timing, and prevent a traffic accident.

Note that, in this specification, a system means a set of a plurality of constituent elements (apparatuses, modules (parts), and the like), and it does not matter whether or not all the constituent elements are provided in the same casing. Thus, a plurality of apparatuses stored in separate casings and connected via a network, and a single apparatus in which a plurality of modules is stored in a single casing are both regarded as systems.

Furthermore, an embodiment of the present technology is not limited to the above-described embodiment, and various changes can be made without departing from the scope of the present technology.

Note that effects described in this specification are mere exemplifications, and are not limited, and effects other than those described in this specification may be caused.

Note that the present technology can employ the following configurations.

(1) A light receiving device including:

a measurement unit configured to measure time information from a light emission timing of a light source to a light receiving timing at which a light receiving element receives light; and

a histogram generation circuit configured to generate a histogram that can accumulate N bits as frequency values on the basis of the time information,

in which the histogram generation circuit includes

a low-order bit generation unit configured to operate at a first speed, and generate a low-order bit of the N bits, and

a high-order bit generation unit configured to operate at a second speed slower than the first speed, and generate a high-order bit of the N bits.

(2) The light receiving device according to (1) described above,

in which the low-order bit generation unit includes an FF circuit configured to store the low-order bit, and

the high-order bit generation unit includes an SRAM or a DRAM configured to store the high-order bit.

(3) The light receiving device according to (1) or (2) described above,

in which the high-order bit generation unit includes a control unit and a memory unit configured to store the high-order bit, and

the control unit controls the memory unit on the basis of a bit indicating carry of the low-order bit of the low-order bit generation unit.

(4) The light receiving device according to (3) described above,

in which the control unit periodically checks the bit, and updates a frequency value of the memory unit that corresponds to carry of the low-order bit.

(5) The light receiving device according to (3) described above,

in which, in a case where the control unit acquires a trigger signal indicating on of the bit, the control unit checks the bit, and updates a frequency value of the memory unit that corresponds to carry of the low-order bit.

(6) The light receiving device according to any of (1) to (5) described above,

in which the light receiving device includes one chip having a stack structure of three substrates.

(7) The light receiving device according to (6) described above, in which the three substrates include

a first substrate on which a pixel array is formed,

a second substrate on which the low-order bit generation unit is formed, and

a third substrate on which the high-order bit generation unit is formed.

(8) A histogram generation method of a light receiving device including

a measurement unit configured to measure time information from a light emission timing of a light source to a light receiving timing at which a light receiving element receives light, and

a histogram generation circuit configured to generate a histogram that can accumulate N bits as frequency values on the basis of the time information,

the histogram generation method including:

the measurement unit measuring the time information; and

the histogram generation circuit operating at a first speed, and generating a low-order bit of the N bits in the histogram on the basis of the time information, and operating at a second speed slower than the first speed, and generating a high-order bit of the N bits in the histogram on the basis of the time information.

(9) A distance measurement system including:

an illumination device configured to emit illumination light; and

a light receiving device configured to receive reflected light of the illumination light,

in which the light receiving device includes

a measurement unit configured to measure time information from a light emission timing of a light source to a light receiving timing at which a light receiving element receives light, and

a histogram generation circuit configured to generate a histogram that can accumulate N bits as frequency values on the basis of the time information, and

the histogram generation circuit includes

a low-order bit generation unit configured to operate at a first speed, and generate a low-order bit of the N bits, and

a high-order bit generation unit configured to operate at a second speed slower than the first speed, and generate a high-order bit of the N bits.

### REFERENCE SIGNS LIST

11 Distance measurement system
21 Illumination device
22 Imaging device
31 Illumination control unit
32 Light source
41 Imaging unit
42 Control unit
52 Light receiving device
71 Pixel drive unit
72 Pixel array
73 MUX
74 Time measurement unit
75 Signal processing unit
76 Input-output unit
81 Pixel
91 TDC
101 SPAD
121 Histogram generation circuit
122A Low-order bit generation unit
122B High-order bit generation unit
131 Decoder
132₁ to 132_{M}FF circuit
133₁ to 133_{M} Carry bit
134 OR circuit
135 Trigger signal generation unit
136 Signal line
141 Control unit
142 Memory unit
192A First substrate
192B Second substrate
192C Third substrate

1. A light receiving device comprising:
a measurement unit configured to measure time information from a light emission timing of a light source to a light receiving timing at which a light receiving element receives light; and
a histogram generation circuit configured to generate a histogram that can accumulate N bits as frequency values on a basis of the time information,
wherein the histogram generation circuit includes
a low-order bit generation unit configured to operate at a first speed, and generate a low-order bit of the N bits, and
a high-order bit generation unit configured to operate at a second speed slower than the first speed, and generate a high-order bit of the N bits.

2. The light receiving device according to claim 1,
wherein the low-order bit generation unit includes an FF circuit configured to store the low-order bit, and
the high-order bit generation unit includes an SRAM or a DRAM configured to store the high-order bit.

3. The light receiving device according to claim 1,
wherein the high-order bit generation unit includes a control unit and a memory unit configured to store the high-order bit, and
the control unit controls the memory unit on a basis of a bit indicating carry of the low-order bit of the low-order bit generation unit.

4. The light receiving device according to claim 3,
wherein the control unit periodically checks the bit, and updates a frequency value of the memory unit that corresponds to carry of the low-order bit.

5. The light receiving device according to claim 3,
wherein, in a case where the control unit acquires a trigger signal indicating on of the bit, the control unit checks the bit, and updates a frequency value of the memory unit that corresponds to carry of the low-order bit.

6. The light receiving device according to claim 1,
wherein the light receiving device includes one chip having a stack structure of three substrates.

7. The light receiving device according to claim 6, wherein the three substrates include
a first substrate on which a pixel array is formed,
a second substrate on which the low-order bit generation unit is formed, and
a third substrate on which the high-order bit generation unit is formed.

8. A histogram generation method of a light receiving device including
a measurement unit configured to measure time information from a light emission timing of a light source to a light receiving timing at which a light receiving element receives light, and
a histogram generation circuit configured to generate a histogram that can accumulate N bits as frequency values on a basis of the time information,
the histogram generation method comprising:
the measurement unit measuring the time information; and
the histogram generation circuit operating at a first speed, and generating a low-order bit of the N bits in the histogram on a basis of the time information, and operating at a second speed slower than the first speed, and generating a high-order bit of the N bits in the histogram on a basis of the time information.

9. A distance measurement system comprising:
an illumination device configured to emit illumination light; and
a light receiving device configured to receive reflected light of the illumination light,
wherein the light receiving device includes
a measurement unit configured to measure time information from a light emission timing of a light source to a light receiving timing at which a light receiving element receives light, and
a histogram generation circuit configured to generate a histogram that can accumulate N bits as frequency values on a basis of the time information, and
the histogram generation circuit includes
a low-order bit generation unit configured to operate at a first speed, and generate a low-order bit of the N bits, and
a high-order bit generation unit configured to operate at a second speed slower than the first speed, and generate a high-order bit of the N bits.
